(19) United States
(12) Patent Application Publication
(10) Pub. No.: US 2025/0259957 A1
(43) Pub. Date: Aug. 14, 2025

(54) ELECTRONIC MODULE

(71) Applicant: SHINDENGEN ELECTRIC MANUFACTURING CO., LTD., Tokyo (JP)

(72) Inventors: Soichiro UMEDA, Saitama (JP); Atsushi KYUTOKU, Saitama (JP)

(21) Appl. No.: 19/052,275

(22) Filed: Feb. 13, 2025

(30) Foreign Application Priority Data
Feb. 14, 2024 (JP) 2024-020366

(51) Int. Cl. H01L 23/00; H01L 23/373; H01L 23/498

(52) U.S. Cl. CPC H01L 24/26; H01L 23/49844; H01L 24/32; H01L 23/3735; H01L 23/49811; H01L 23/49833; H01L 2224/2612; H01L 2224/32225; H01L 2924/13091; H01L 2924/351

(57) ABSTRACT

An electronic module includes an internal connection terminal having conductivity that is electrically connected to an electronic element, and a spacer is disposed between a lower end surface of the internal connection terminal and the electronic element. Solder BM1 is disposed between the electronic element and the spacer, and a stepped portion is formed along an outer peripheral portion of the spacer.

### CROSS REFERENCE TO RELATED APPLICATIONS

This application claims priority to Japanese Patent Application No. 2024-20366, filed on Feb. 14, 2024, which is expressly incorporated herein by reference in its entirety.

### TECHNICAL FIELD

The present invention relates to an electronic module.

### BACKGROUND ART

Conventionally, there has been known an electronic module that includes: an electronic element (for example, a chip); a board on which the electronic element is mounted; and a pin terminal that forms an internal connection terminal which is connected to a wiring pattern on the board (hereinafter, referred to patent literature 1). Among electronic modules of this type, there has been known an electronic module where the internal connection terminal is connected to an electrode of an electronic element in place of a wiring pattern. As such an electronic module, there exists an electronic module where an internal connection terminal is connected to an electrode of an electronic element via a spacer having a flat plate shape (for example, a chip spacer). In this case, the spacer and the electrode of the electronic element are bonded to each other by solder.

To be more specific, as illustrated in FIG. 7, an electronic element 320 is disposed on a board 312, and is bonded to the board 312 by solder BM30. A chip spacer 318 us disposed on the electronic element 320, and is bonded to the electronic element 320 via solder BM10. A lower end of an inner connection terminal 334 is disposed on the chip spacer 318, and the inner connection terminal 334 is bonded to the chip spacer 318 by solder BM20.

### PRIOR ART LITERATURE

### Patent Literature

[Japanese Patent Literature 1] Japanese Patent No. 6850938

### SUMMARY OF INVENTION

### Technical Problem

The spacer is used for alleviating a thermal stress that acts in solder between an electronic element and an internal connection terminal. In a case where a large electronic element is mounted or a highly reliable withstand strength is necessary, it is further necessary to alleviate a thermal stress. Accordingly, it is necessary to secure solder having a predetermined thickness on an outer peripheral portion of a spacer which is a thermal stress concentrating portion in a bonding portion between the spacer and an electronic element.

On the other hand, an amount of solder which can be applied by coating to electrodes of an electronic element for preventing a solder bridge between electrodes having different polarities on the electronic element is restricted. Accordingly, in the above-mentioned conventional structure, it is difficult to secure a sufficient solder thickness on the outer peripheral portion.

The present invention has been made in view of the above-mentioned drawbacks, and it is an object of the present invention to provide an electronic module that can secure a predetermined solder thickness on an outer peripheral portion of a spacer which is a thermal stress concentrating portion in a bonding portion between a spacer and an electronic element, and can alleviate a thermal stress generated in the outer peripheral portion of the spacer.

### Solution to Problem

An electronic module according to the present invention includes: an electronic element; an internal connection terminal having conductivity that is electrically connected to the electronic element; and a spacer disposed between a lower end surface of the internal connection terminal and the electronic element, wherein a conductive bonding material is disposed between the electronic element and the spacer, and a stepped portion is formed along an outer peripheral portion of the spacer.

### Advantageous Effects of the Present Invention

The electronic module according to the embodiment includes: the electronic element; the internal connection terminals having conductivity that are electrically connected to the electronic element; and the spacer disposed between the lower end surfaces of the internal connection terminals and the electronic element, wherein the conductive bonding material is disposed between the electronic element and the spacer, and the stepped portion is formed along the outer peripheral portion of the spacer. With such a configuration, a space for securing a proper solder thickness can be formed between the stepped portion formed on the outer peripheral portion of the spacer and the electronic element. Accordingly, it is possible to secure a predetermined solder thickness on the outer peripheral portion of the spacer that forms a thermal stress concentrating portion. As a result, it is possible to alleviate a thermal stress that is generated on the outer peripheral portion of the spacer at the bonding portion between the spacer and the electronic element.

### BRIEF DESCRIPTION OF DRAWINGS

FIG. 1 is an external appearance perspective view of an electronic module 100 according to an embodiment.

FIG. 2 is a perspective view illustrating the internal structure of the electronical module 100 according to the embodiment.

FIG. 3 is a perspective view illustrating a peripheral structure of a spacer 122 in the embodiment. In FIG. 3, symbol 135 indicates a flange portion, and symbol 144 indicates an internal connection terminal.

FIG. 4 is a cross-sectional view taken along A-A in FIG. 3.

FIG. 5 is a perspective view illustrating the structure of a lower surface of the spacer 122 in the embodiment.

FIG. 6 is a perspective view illustrating the structure of an upper surface of the spacer 122 in the embodiment.

FIG. 7 is a view illustrating an electronic module according to a prior art.

### DESCRIPTION OF EMBODIMENTS

Hereinafter, the electronic module according to the present invention is described based on an embodiment illustrated in the drawings. The embodiment described hereinafter is not intended to limit the present invention called for in claims. Further, it is not always the case that all of various elements described in the embodiment and combinations of these elements are indispensable as means to solve the problem of the present invention.

### EMBODIMENT

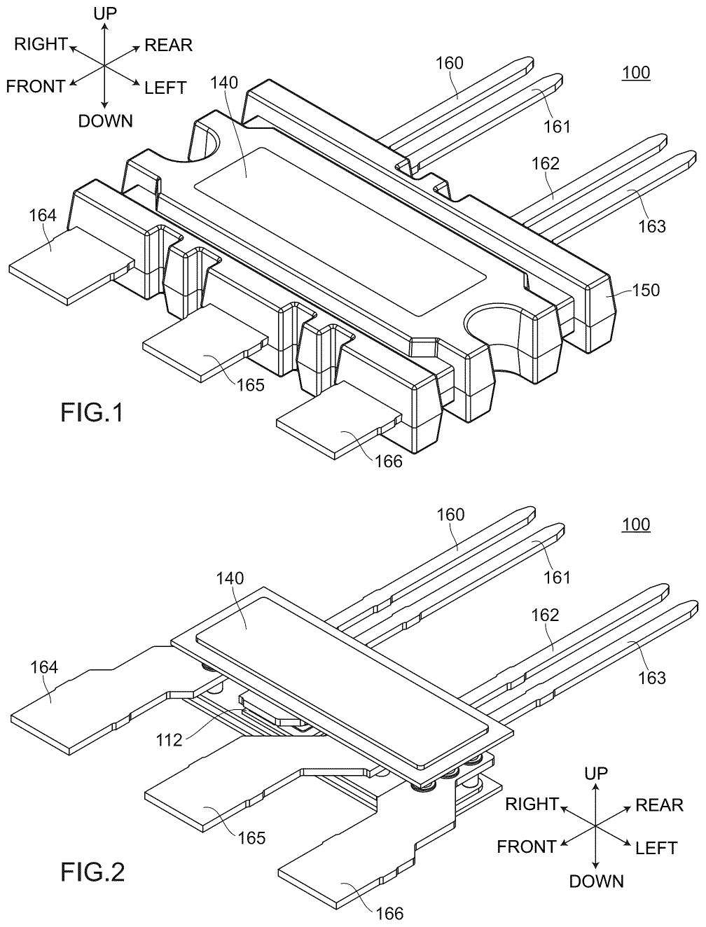

As illustrated in FIG. 1 to FIG. 3, an electronic module 100 according to the embodiment includes: a board (first board) 112; an electronic element 120; a spacer (chip spacer) 122; an internal connection terminal 134; a board (second board) 140; and a lead frame (constituting external connection terminals, hereinafter, referred to as “external connection terminals”) 160, 161, 162, 163, 164, 165, 166; and a mold resin 150. The external connection terminal 161 is connected to the internal connection terminal 134 at an intermediate position of the internal connection terminal 134. The electronic element (semiconductor element) 120 is bonded to an upper surface of the board 112 by solder BM3 (see FIG. 4), and an electronic element (semiconductor element: not illustrated in the drawing) is bonded to a lower surface of the board 140 via solder.

In the embodiment, the electronic module 100 is provided for constituting a half bridge circuit. For example, the electronic element 120 is used on a high side, and the electronic element bonded to the lower surface of the board 140 is used on a low side. There also may be a case where the electronic element 120 is used on the low side, and the electronic element bonded to the lower surface of the board 140 is used on the high side. The electronic module 100 may include constitutional elements other than the above-mentioned constitutional elements. Hereinafter, for the sake of convenience, the constitutional elements in the electronic element 120 of the electronic module 100 are described, and the detailed description of the constitutional elements of the electronic element bonded to the lower surface of the board 140 is omitted. In the present specification, the phrase “electrically connected” means not only the case where electricity supply portions of constitutional elements are directly brought into contact with each other but also a case where the electricity supply portions of the constitutional elements are bonded to each other via an additional constitutional element having conductivity (for example, solder or a spacer).

The board 112 is a board having the structure where a copper plate is disposed on both surfaces of a ceramic plate (for example, DCB board). The board 112 is electrically connected to a drain electrode (not illustrated in the drawing) of the electronic element 120. The board 112 is not limited to the DCB board, and may be a printed board or the like, for example.

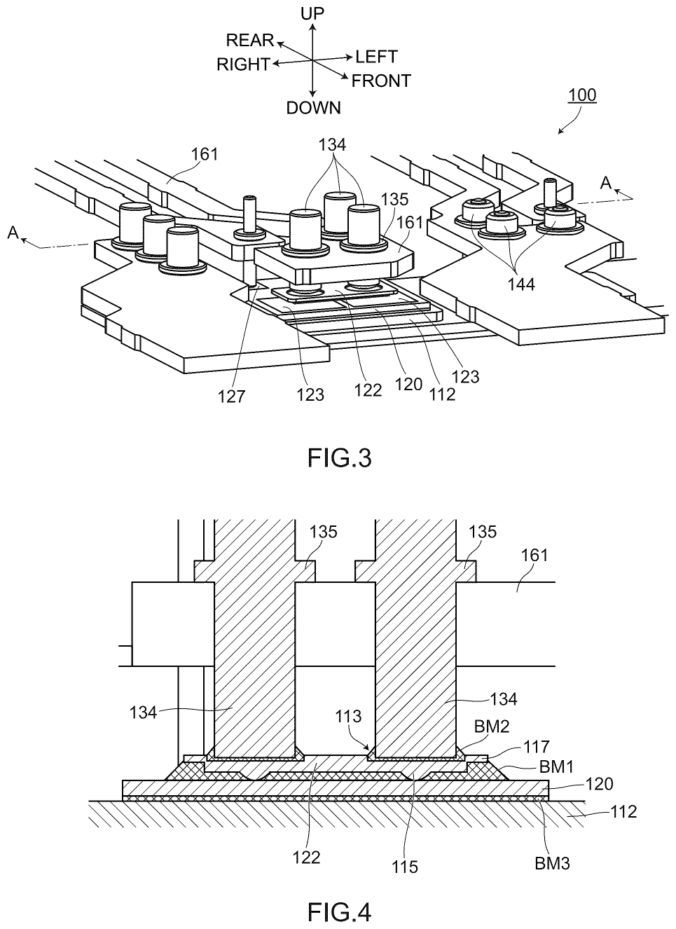

The electronic element 120 is disposed on the board 112. The electronic element 120 is a vertical-type MOSFET having a source electrode 123 disposed on a side opposite to a board 112 side, a drain electrode (not illustrated in the drawing) disposed on a board 112 side, and a gate electrode 127 disposed on the same side as the source electrode 123 (see FIG. 3). The electronic element 120 includes three source electrodes 123 as the source electrode.

The inner connection terminal 134 is a member having an approximately columnar shape and having conductive property (see FIG. 4), and is connected to the spacer 122 having a flat plate shape which is made of a conductive material via a through hole (symbol being omitted) formed in the external connection terminal 161. The inner connection terminal 134 is connected to the board 112 and the board 140. The electronic module 100 includes three internal connection terminals 134 corresponding to the state that the electronic element 120 includes three source electrodes 123. In the embodiment, the description has been made by taking the case where the inner connection terminal 134 has an approximately columnar shape as an example. However, the inner connection terminal 134 is not limited to the approximately columnar internal connection terminal, and may be an internal connection terminal having a flat shape, for example.

A lower surface of the spacer 122 is bonded to the source electrode 123 of the electronic element 120 via a conductive bonding member (for example, solder) BM1. An upper surface of the spacer 122 is bonded to a lower end surface of the internal connection electrode 134 via solder BM2.

The external connection terminal 161 is a member that is electrically connected to the internal connection terminal 134, and at least one end the external connection terminal 161 protrudes toward the outside from the mold resin 150. In the electronic module 100. the external connection terminal 161 is a detection terminal for the source electrode 123 of the electronic element 120.

### (Structure of Spacer)

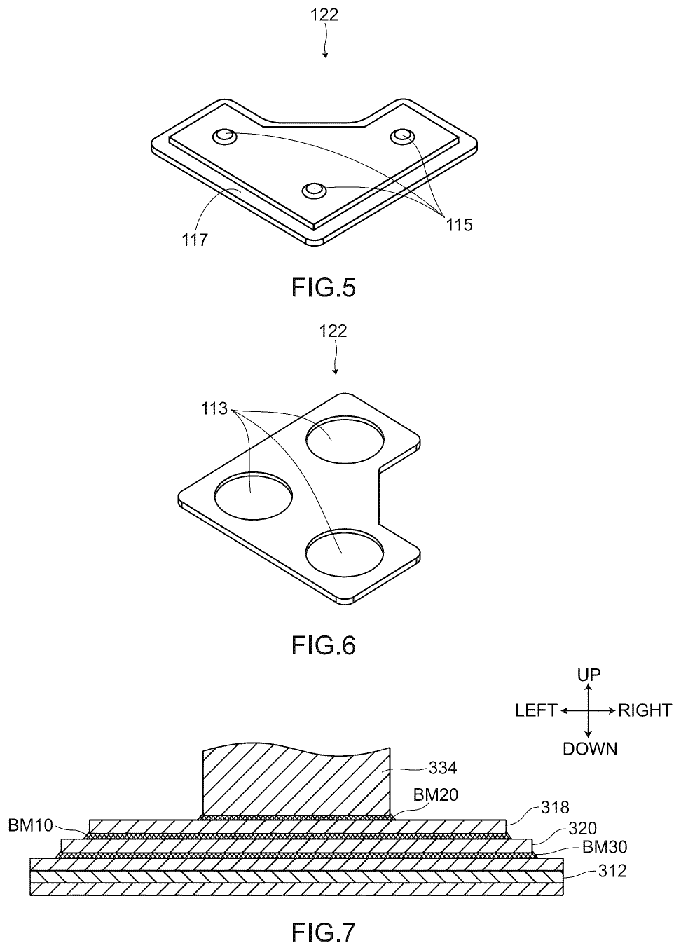

As illustrated in FIG. 5 and FIG. 6, the spacer 122 is a thin flat member (a copper plate) having conductivity that is formed in a polygonal shape. On an upper surface of the spacer 122, three annular indentations (recessed portions) 113 each having an outer diameter larger than a diameter of the inner connection terminal 134 are formed (see FIG. 6). The spacer 122 is bonded to a lower surface of the inner connection terminals 134 by way of a conductive bonding material (for example, solder BM2) at indentations 113. The indentations 113 are formed by applying a force in the vertical direction by pressing from above. An external appearance shape of the indentation 113 conforms to a cross-sectional shape of the internal connection terminal 134, and an outer diameter and a depth of the indentation 113 can be changed corresponding to a shape of the internal connection terminal 134. A lower surface of the spacer 122 is bonded to an upper surface (to be more specific, the source electrode 123) of the electronic element 120 by way of a conductive bonding material (for example, solder BM1).

The annular indentations 113 each having an outer diameter larger than an outer diameter of the internal connection terminal 134 are formed on the spacer 122. With the formation of such an indentation 113, it is possible to prevent solder BM2 from flowing out from between an upper surface of the spacer 122 and a lower surface of the inner connection terminal 134 to the outside in a radial direction.

Further, as illustrated in FIG. 5, a stepped portion (a depressed portion) 117 is formed along an outer peripheral portion of the spacer 122. Accordingly, a space is formed between the stepped portion 117 formed on the outer peripheral portion of the spacer 122 and the electronic element 120. Accordingly, compared to a conventional spacer on which a stepped portion is not formed, a thickness of solder between the lower surface of the spacer 122 and the electronic element 120 at the outer peripheral portion can be largely increased.

On a lower surface of the spacer 122, protruding portions 115 that bring the internal connection terminals 134 and source electrodes 123 of the electronic elements 120 into a point contact with each other are formed via the spacer 122. With the formation of the protruding portions 115, a distance between portions of the bottom portion of the spacer 122 other than the protruding portions 115 and the electronic element 120 can be held at a fixed value. Accordingly, a solder thickness of solder BM1 disposed between the spacer 122 and the electronic element 120 can be held at a fixed value (see FIG. 4).

Further, it is preferred that the positions where the indentations 113 and the protruding portions 115 are formed correspond to the positions where the inner connection terminals 134 are formed, and are formed inside an outer periphery of the spacer 122. It is preferred that the number of indentations 113 and the number of protruding portions 115 are respectively at least three, for example. The reason is that such arrangement and the numbers enable the self-standing of the spacer 122. That is, to enable the self-standing of the spacer 122, it is necessary that the protruding portions 115 at three points or more are not disposed on one straight line.

### Advantageous Effects Acquired by Embodiment

The electronic module 100 according to the embodiment includes: the electronic element 120; the internal connection terminals 134 having conductivity that are electrically connected to the electronic element 120; and the spacer 122 disposed between the lower end surfaces of the internal connection terminals 134 and the electronic element 120, wherein solder BM1 is disposed between the electronic element 120 and the spacer 122, and the stepped portion 117 is formed along the outer peripheral portion of the spacer 122. With such a configuration, the space for securing a proper solder thickness can be formed between the stepped portion 117 formed on the outer peripheral portion of the spacer 122 and the electronic element 120.

Accordingly, it is possible to secure a predetermined solder thickness on the outer peripheral portion of the spacer 122 that forms a thermal stress concentrating portion. As a result, it is possible to alleviate a thermal stress that is generated on the outer peripheral portion of the spacer 122 at the bonding portion between the spacer 122 and the electronic element 120.

Further, in the electronic module 100 according to the embodiment, the protruding portions 115 provided for electrically connecting the internal connection terminals 134 and the electronic element 120 are formed on the lower surface of the spacer 122. Due to the formation of the protruding portions 115, the distance between portions of the bottom portion of the spacer 122 other than the protruding portions 115 and the electronic element 120 can be held at a fixed value. As the result, a solder thickness of solder BM1 disposed between the portions of the bottom portion of the spacer 122 other than the protruding portions 115 and the electronic element 120 can be held at a fixed value. Further, due to the formation of the protruding portions 115, it is possible to generate the self-alignment of solder BM1 at the time of coagulation toward the axes of the internal connection terminals 134.

Further, according to the electronic module 100 of the embodiment, at least three protruding portions 115 are formed and hence, it is possible to make the spacer 122 stand upright.

Further, according to the electronic module 100 of the embodiment, the annular indentations 113 each having outer diameter larger than the diameter of the internal connection terminal 134 are formed on the upper surface of the spacer 122, and the positions where the indentations 113 are formed are set at positions corresponding to the positions of the internal connection terminals 134. Accordingly, it is possible to provide a self-alignment effect to the internal connection terminals 134 inserted into the lead frame 161 and hence, it is possible to prevent the positional displacement of the spacer 122.

### REFERENCE SIGNS LIST

100: electronic module
113: indentation (recessed portion)
115: protruding portion
117: stepped portion
120: electronic element
122: spacer
134: internal connection terminal

1. An electronic module comprising:
an electronic element;
an internal connection terminal having conductivity that is electrically connected to the electronic element; and
a spacer disposed between a lower end surface of the internal connection terminal and the electronic element, wherein
a conductive bonding material is disposed between the electronic element and the spacer, and
a stepped portion is formed along an outer peripheral portion of the spacer.

2. The electronic module according to claim 1, wherein a protruding portion is formed on a surface of the spacer on an electronic element side.

3. The electronic module according to claim 1, wherein, the protruding portion is formed of at least three protruding portions.

4. The electronic module according to claim 2, wherein, the protruding portion is formed of at least three protruding portions.

5. The electronic module according to claim 1, wherein, an annular indentation having an outer diameter larger than a diameter of the internal connection terminal is formed on an upper surface of the spacer, and the indentation is formed at positions corresponding to a position where the internal connection terminal is positioned.

6. The electronic module according to claim 2, wherein, an annular indentation having an outer diameter larger than a diameter of the internal connection terminal is formed on an upper surface of the spacer, and the indentation is formed at positions corresponding to a position where the internal connection terminal is positioned.
